(19) United States
(12) Patent Application Publication
(10) Pub. No.: US 2009/0218118 A1
(43) Pub. Date: Sep. 3, 2009

(54) BOARD AND MANUFACTURING METHOD FOR THE SAME

(75) Inventor: Motoaki TANI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/393,663

(22) Filed: Feb. 26, 2009

(30) Foreign Application Priority Data
Feb. 29, 2008 (JP) 2008-050955

(51) Int. Cl. H05K 1/18; H05K 3/30

(52) U.S. Cl. 174/256; 29/832

(57) ABSTRACT

A board includes a core board, an electronic component arranged on the core board, and an intermediate layer that includes resin containing carbon fibers and that surrounds the electronic component from the side.

### CROSS-REFERENCE TO RELATED APPLICATIONS

This application is based upon and claims the benefit of priority from the prior Japanese Patent Application No. 2008-050955, filed on Feb. 29, 2008, the entire contents of which are incorporated herein by reference.

### FIELD

The present invention relates to a board and a manufacturing method for the same.

### BACKGROUND

In recent years, size reduction, thickness reduction, performance improvement, and the like are demanded in electronic equipments such as mobile communication devices. This causes demands on size reduction and multilayered construction in wiring boards such as printed circuit boards and on high density mounting of electronic components. Thus, in order that the number of electronic components such as semiconductor devices to be mounted on the surface of a wiring board can be reduced so that the size of the wiring board can be reduced, a device embedded substrate is proposed that has a structure that an electronic component such as a semiconductor device is built in the inside of the wiring board.

A device embedded substrate is formed as follows. First, an electronic component such as a semiconductor device is mounted onto a thin core board. Then, a prepreg that is constructed from glass fiber reinforced plastics in a B-stage state where thermosetting resin is in a semi-cured state and that has an opening for an electronic component mounting region is stacked and cured. This prepreg is formed by impregnating, with thermosetting resin, fibers composed of an insulating material such as glass cloth. Since the prepreg is constructed from the above-mentioned fibers, when an electronic component such as a semiconductor device is to be mounted onto the core board, embedding into the prepreg is difficult. Thus, in the prepreg, an opening is formed that serves as an electronic component mounting region where an electronic component is mounted. Further, the electronic component such as a semiconductor device built in the embedded component substrate is electrically connected to inner layer circuit electrodes of the board.

A wiring board has been proposed that has a core layer constructed from a carbon fiber material and a resin composition containing inorganic fillers, a stacking wiring section that contains an insulating layer formed on the core layer and a wiring pattern provided on the insulating layer, and an electrically conducting section that extends in the thickness direction in the inside of the core layer and that is electrically connected to the wiring pattern in the stacking wiring section (Japanese Laid-Open Patent Publication No. 2004-119691). Further, a multilayer wiring board has been proposed that has a stacking structure constructed from a core part having a core insulating layer that includes a carbon fiber material, a first stacking wiring section that has a stacking structure constructed from at least one first insulating layer that includes glass cloth and from a first wiring pattern and that is joined to the core part, and a second stacking wiring section that has a stacking structure constructed from at least one second insulating layer and a second wiring pattern and that is joined to the first stacking wiring section (Japanese Laid-Open Patent Publication No. 2004-87856).

Further, an electronic-device-built-in multilayer wiring board provided with a built-in electronic device has been proposed that is formed by stacking a plurality of insulating layers constructed from an organic material, then forming wiring conductors on the surfaces of these insulating layers, and then electrically connecting the wiring conductors located up and down of the insulating layers through penetration conductors formed in the insulating layers and that has extraction electrode sections located in the inside of a hollow part in at least one insulating layer and electrically connected to the wiring conductors or the penetration conductors (Japanese Laid-Open Patent Publication No. 2004-296574).

Further, a micro-device-built-in board is proposed that has a first board having first wiring, a micro device mounted on the first board, a resin layer formed on the first board so as to cover an outer peripheral surface of the micro device, fill a gap between the first board and the micro device, and have a surface located at the same height as the upper face of the device board of the micro device, and a second board having second wiring and stacked on the resin layer and the micro device (Japanese Laid-Open Patent Publication No. 2006-351590).

Nevertheless, in a device embedded substrate formed by mounting an electronic component such as a semiconductor device onto a thin core board and then stacking and curing a prepreg constructed from glass fiber reinforced plastics in a B-stage state, components constituting the embedded component substrate have mutually different thermal expansion coefficients.

For example, in a case that the electronic component mounted on the thin core board is a semiconductor device, when the semiconductor device is composed of silicon (Si), its thermal expansion coefficient is approximately 3 ppm/° C. In contrast, when the semiconductor device is composed of gallium arsenide (GaAs), its thermal expansion coefficient is approximately 7 ppm/° C. On the other hand, the cured material of a prepreg containing fibers composed of an insulating material such as glass cloth has a thermal expansion coefficient as high as approximately 15 ppm/° C.

When the semiconductor device is formed thin, this difference between the thermal expansion coefficients of the components constituting the embedded component substrate can cause damage such as fracture and breakage in the semiconductor device. In particular, in association with the demand on thickness reduction in the embedded component substrate, thickness reduction is demanded also in the semiconductor device built in the board. Thus, damage such as fracture and breakage in the semiconductor device is a large problem.

Further, even when the semiconductor device is formed thick, damage can be caused in the semiconductor device in a part where the prepreg contacts with the semiconductor device. Alternatively, satisfactory electrical connection can not be obtained between the semiconductor device and the inner layer circuit electrode of the board. These situations can cause poor reliability in the embedded component substrate.

### SUMMARY

According to an aspect of the invention, a board includes a core board, an electronic component arranged on the core board, and an intermediate layer that includes resin containing carbon fibers and that surrounds the electronic component from the side.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a sectional view of a device embedded substrate according to a first embodiment of the present invention;

FIGS. 2A to 2K are diagrams describing a manufacturing method for a device embedded substrate illustrated in FIG. 1;

FIG. 3 is a supplementary diagram describing a manufacturing method for a device embedded substrate according to a first embodiment of the present invention;

FIG. 4 is a sectional view of a device embedded substrate according to a second embodiment of the present invention;

FIGS. 5A to 5J are diagrams describing a manufacturing method for a device embedded substrate illustrated in FIG. 4;

FIG. 6 is a supplementary diagram describing a manufacturing method for a device embedded substrate according to a second embodiment of the present invention;

FIGS. 7A to 7I are diagrams describing a manufacturing method for a device embedded substrate according to a third embodiment of the present invention.

### DESCRIPTION OF EMBODIMENTS

### First Embodiment

First, the structure of a device embedded substrate according to a first embodiment of the present invention is described below. Then, description is given concerning a manufacturing method for a device embedded substrate according to the first embodiment of the present invention and an example of application of this method implemented by the present inventor.

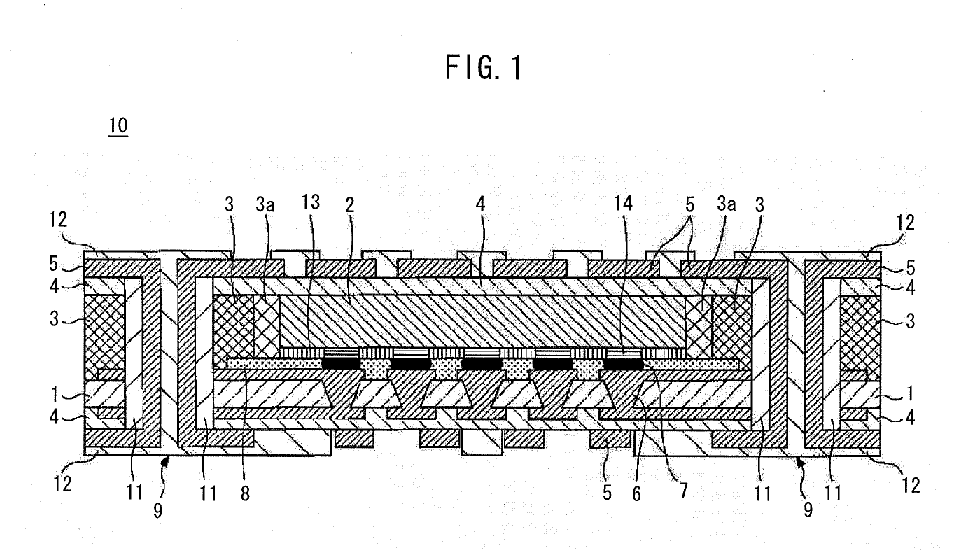

FIG. 1 is a sectional view of a device embedded substrate according to the first embodiment of the present invention.

The embedded component substrate 10 according to the first embodiment of the present invention includes a core board 1, a semiconductor integrated circuit device (referred to as a semiconductor device, hereinafter) 2 mounted on the core board 1, an intermediate layer 3 provided on the core board 1 so as to include the semiconductor device 2, a prepreg 4 provided so as to sandwich the core board 1, the semiconductor device 2, and the intermediate layer 3, and wiring sections 5 formed on the prepreg 4.

The core board 1 is constructed from a glass fiber reinforced plastics material or the like that employs glass fibers or the like as a reinforcing material and epoxy resin or the like as a matrix resin. The core board 1 is contained in the inner layer of the embedded component substrate 10. For example, the thickness of the core board 1 is approximately 0.03 mm to 0.3 mm.

In the core board 1, a plurality of connection terminal sections 6 that penetrate from the upper face to the lower face are formed at a given pitch. For example, the connection terminal sections 6 are constructed from copper (Cu) wiring or alternatively from copper (Cu) wiring on which a nickel (Ni) film and a gold (Au) film are formed.

In the core board 1, the semiconductor device 2 serving as an electronic component is mounted in a face-down state, that is, flip chip mounting is performed. The semiconductor device 2 is composed of silicon (Si), gallium arsenide (GaAs), or the like and has a thermal expansion coefficient of approximately 1 ppm/° C. to 10 ppm/° C. Further, the semiconductor device 2 may be composed of a so-called bare chip or a wafer level chip size package, and has a thickness of, for example, approximately 0.1 mm.

In the principal surface of the semiconductor device 2, an organic compound insulator film 13 such as a polyimide film is formed selectively. Then, in the part where the organic compound insulator film 13 is not formed, a plurality of electrically conducting sections 14 are formed. On each electrically conducting section 14, a protruding external connection terminal 7 referred to as a stud bump is formed. The external connection terminals 7 are composed of gold (Au) or the like. The external connection terminals 7 of the semiconductor device 2 are connected to the connection terminal sections 6 formed on the core board 1.

In the gap between the core board 1 and the semiconductor device 2, an under-fill material 8 is provided that is composed of thermosetting adhesive such as epoxy family resin, polyimide family resin, or acrylic family resin depending on the necessity. The under-fill material 8 reinforces the connection between the core board 1 and the semiconductor device 2.

On the core board 1, the intermediate layer 3 is formed so as to include the above-mentioned semiconductor device 2. Specifically, the intermediate layer 3 is stacked and formed so as to surround the semiconductor device 2 in the part on the core board 1 except for the part where through holes 9 described later are formed and the part where the semiconductor device 2 is provided.

Preferably, the film thickness of the intermediate layer 3 is equal to the thickness of the semiconductor device 2, and hence set equal to, for example, approximately 0.1 mm.

The intermediate layer 3 is constructed from reinforced resin obtained by impregnating a carbon fiber material with a resin material having a thermal expansion coefficient of approximately 1 ppm/° C. to 10 ppm/° C. The employed carbon fiber material may be, for example, carbon fiber cloth, carbon fiber mesh, or carbon fiber nonwoven fabric that is fabricated with carbon fiber threads formed from bundles of carbon fibers. The resin material for including the carbon fiber material may be epoxy resin or the like.

A resin material 3a is squeezed out from the intermediate layer by pressurization in the manufacturing process for the embedded component substrate 10.

The prepreg 4 is provided so as to sandwich the wiring board 1, the semiconductor device 2, and the intermediate layer described above. Similarly to the core board 1, the prepreg serving as an insulating layer is constructed from a glass fiber reinforced plastics material or the like that employs glass fibers or the like as a reinforcing material and epoxy resin or the like as a matrix resin. The thickness of the prepreg 4 may be set equal to, for example, approximately 0.1 mm.

On the prepreg 4, the wiring sections 5 are formed that are constructed from copper (Cu) or the like. Further, in the outside of the two side faces of the semiconductor device 2 mounted on the core board 1, through holes 9 are formed that penetrate the prepreg 4, the intermediate layer 3, the core board 1, and the like.

On an inner wall surface of the through hole 9, insulating resin 11 is formed that is constructed from epoxy resin or the like. On the insulating resin 11 in the through holes 9, for example, a copper (Cu) plating film is formed so that the above-mentioned wiring sections 5 are constructed. The insulating resin 11 ensures insulation between the wiring section 5 formed in each through hole 9 and the intermediate layer 3 constructed from reinforced resin obtained by impregnating a carbon fiber material with a resin material.

Here, in the example illustrated in FIG. 1, single-layer wiring sections 5 are formed on the prepreg 4. However, a multilayered circuit may be formed by a buildup construction method or a batch stacking construction method.

On the wiring sections 5 and the prepreg 4, a solder resist layer (insulating resin film) 12 is formed selectively. The solder resist is composed of resin of epoxy family, acrylic family, polyimide family, or the like, or alternatively resin a mixture of these. The surfaces of the wiring sections 5 where the solder resist layer 12 is not provided and hence exposed are processed by surface treatment.

As such, according to the embedded component substrate 10 of the first embodiment of the present invention, the intermediate layer 3 constructed from a reinforced resin material composed of a carbon fiber material having a thermal expansion coefficient of approximately 1 ppm/° C. to 10 ppm/° C. which is lower than that of a prepreg containing fibers composed of an insulating material such as glass cloth is stacked and formed on the core board 1 so as to include the semiconductor device 2, that is, so as to surround the semiconductor device 2 in the part on the core board 1 except for the part where the through holes 9 are formed and the part where the semiconductor device 2 is provided.

Thus, in comparison with a conventional embedded component substrate formed when a prepreg constructed from a glass fiber reinforced plastics material having an opening in the mounting region for a semiconductor device is stacked on a core board on which a semiconductor device is mounted, the present invention suppresses the occurrence of the problems of damage to the semiconductor device and poor electrical connection between the semiconductor device and the core board that are caused by the difference between the thermal expansion coefficients of the components constituting the embedded component substrate.

Next, a manufacturing method for the embedded component substrate 10 having this structure is described below.

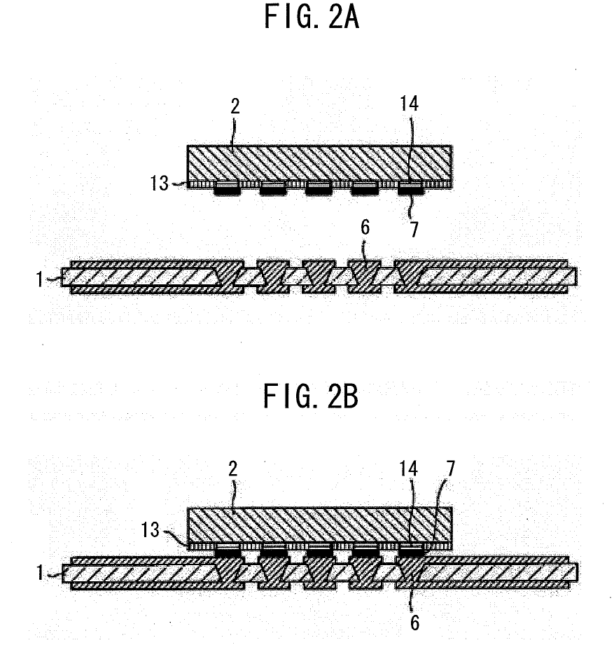

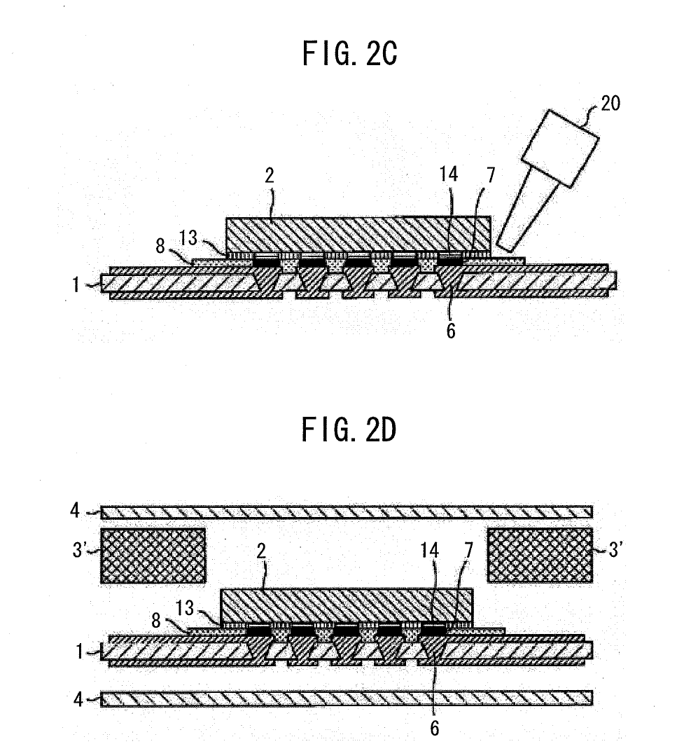

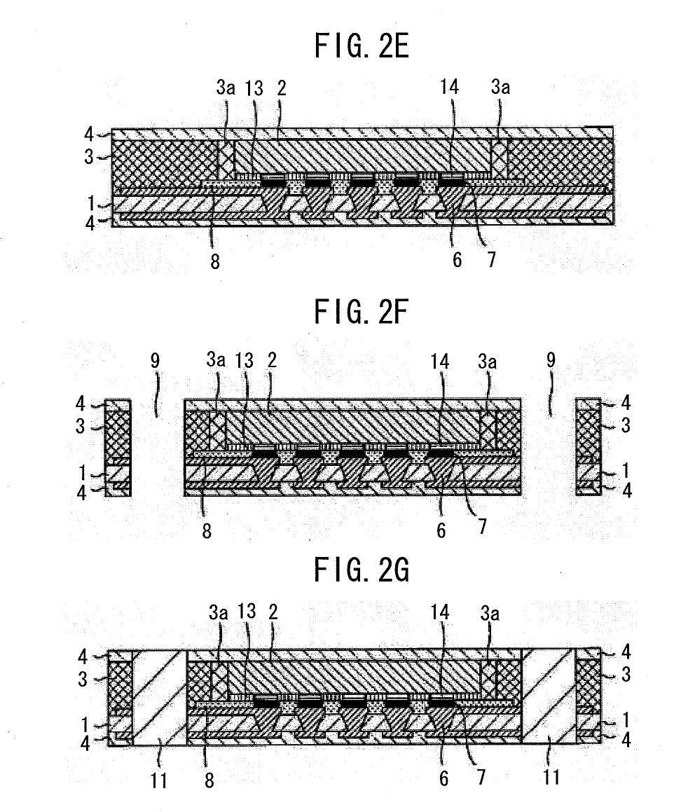

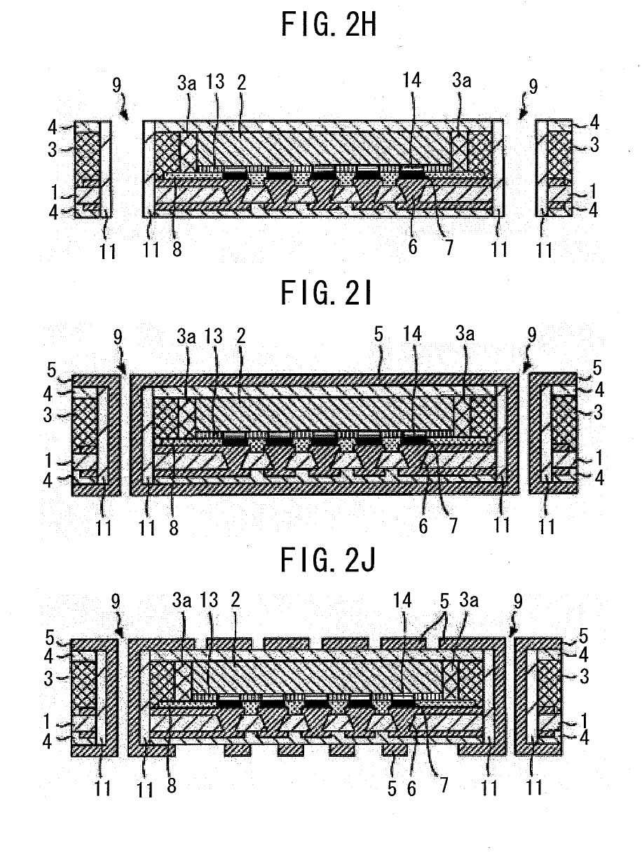

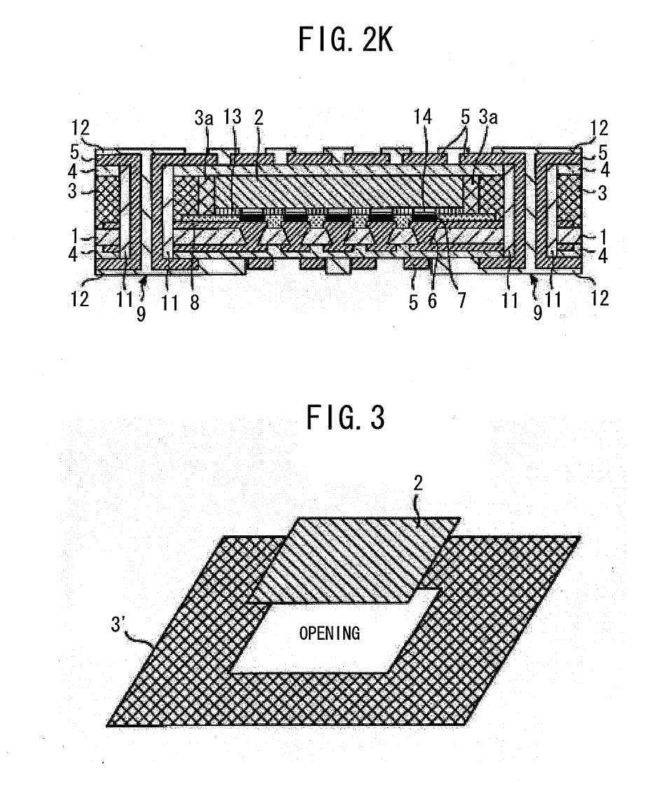

In the manufacturing method of the embedded component substrate 10, first, a core board 1 and a semiconductor device 2 are prepared as illustrated in FIG. 2A.

The core board 1 is constructed from a glass fiber reinforced plastics material or the like that employs glass fibers or the like as a reinforcing material and epoxy resin as a matrix resin. The thickness of the core board 1 may be set equal to, for example, approximately 0.03 mm to 0.3 mm.

In the core board 1, a plurality of connection terminal sections 6 that penetrate from the upper face to the lower face are formed at a given pitch. For example, the connection terminal sections 6 are constructed from copper (Cu) wiring or alternatively from copper (Cu) wiring on which a nickel (Ni) film and a gold (Au) film are formed.

On the other hand, the semiconductor device 2 is formed by a well-known wafer process, and includes silicon (Si), gallium arsenide (GaAs), or the like. The semiconductor device 2 may be composed of a so-called bare chip or a wafer level chip size package, and has a thickness of, for example, approximately 0.1 mm.

In the principal surface of the semiconductor device 2, an organic compound insulator film 13 such as a polyimide film is formed selectively. Then, in the part where the organic compound insulator film 13 is not formed, a plurality of electrically conducting sections 14 are formed. On each electrically conducting section 14, a protruding external connection terminal 7 referred to as a stud bump is formed. The external connection terminals 7 are composed of gold (Au) or the like.

The semiconductor device 2 is placed onto the core board 1 in a state that the connection terminal sections 6 of the core board 1 having the above-mentioned structure face the external connection terminals 7 provided in the semiconductor device 2.

Then, as illustrated in FIG. 2B, the semiconductor device 2 is mounted in a face-down state onto the connection terminal sections 6 of the core board 1. That is, flip chip mounting is performed. The employed method of flip chip mounting may be thermocompression bonding, ultrasonic jointing, or the like. Further, when solder is employed in the external connection terminals 7, the employed method of flip chip mounting may be a method of employing solder balls or a method of adhering solder onto the electrically conducting sections 14.

After that, as illustrated in FIG. 2C, paste-state under-fill material 8 is injected from a dispenser (not illustrated) through a nozzle 20, and then cured. The under-fill material 8 reinforces the connection between the core board 1 and the semiconductor device 2. Here, when the employed method of flip chip mounting is thermocompression bonding, the under-fill material 8 may be injected into the gap between the core board 1 and the semiconductor device 2, then the semiconductor device 2 may be flip-chip-mounted onto the core board 1, and then the under-fill material 8 may be cured and shrunk.

Then, as illustrated in FIG. 2D, a reinforced resin material 3′ that is constructed from a carbon fiber material in a B-stage state and that has an opening slightly larger than the mounting region for the semiconductor device 2 on the core board 1 is stacked onto the core board 1 so that an intermediate layer 3 illustrated in FIG. 1 is formed. Here, the B-stage state indicates a state that thermosetting resin is semi-cured.

The positional relation between the reinforced resin material 3′ and the semiconductor device 2 at that time is illustrated in FIG. 3. FIG. 3 is a schematic diagram illustrating a perspective view of a situation that a reinforced resin material 3′ that is constructed from a carbon fiber material in a B-stage state and that has an opening slightly larger than the mounting region for the semiconductor device 2 on the core board 1 is stacked onto the core board 1. As illustrated in FIG. 3, an opening slightly larger than the mounting region for the semiconductor device 2 is formed approximately in the center of the reinforced resin material 3′. Then, the semiconductor device 2 is located inside the opening.

The reinforced resin material 3′ employing a carbon fiber material may be constructed from reinforced resin obtained by impregnating a carbon fiber material with a resin material having a thermal expansion coefficient of approximately 1 ppm/° C. to 10 ppm/° C. The employed carbon fiber material may be, for example, carbon fiber cloth, carbon fiber mesh, or carbon fiber nonwoven fabric that is fabricated with carbon fiber threads formed from bundles of carbon fibers and that is oriented so as to extend in the directions of surface broadening. The resin material for including the carbon fiber material may be epoxy resin or the like.

The reinforced resin material 3′ employing a carbon fiber material is cured at a process step illustrated in FIG. 2E. It is preferable that the after-the-curing film thickness of the reinforced resin material 3′ (the intermediate layer 3) is equal to the thickness of the semiconductor device 2. Thus, the thickness is set equal to, for example, approximately 0.1 mm.

After the reinforced resin material 3′ employing a carbon fiber material is stacked onto the core board 1, the prepreg 4 constructed from a glass fiber reinforced plastics material or the like that employs glass fibers or the like as a reinforcing material and epoxy resin or the like as a matrix resin similarly to the core board 1 is stacked onto the reinforced resin material 3′ and the semiconductor device 2 and onto the lower face of the core board 1. The thickness of the prepreg 4 may be set equal to, for example, approximately 0.1 mm.

Then, as illustrated in FIG. 2E, the reinforced resin material 3′ employing a carbon fiber material and the prepreg 4 are heated at a temperature of approximately 180° C. to 250° C. and simultaneously pressurized at a pressure of approximately 1.7 MPa to 5 MPa so as to be cured. Then, in the part opposing to the side faces and the lower face of the semiconductor device 2, the resin material 3a is squeezed out from reinforced resin material 3′ or the prepreg 4.

After that, as illustrated in FIG. 2F, in the outside of the two side faces of the semiconductor device 2 mounted on the core board 1, that is, in the outside of the mounting region for the semiconductor device 2, through holes 9 that penetrate the prepreg 4, the intermediate layer 3, and the core board 1 are formed, for example, by drilling.

Then, as illustrated in FIG. 2G, insulating resin 11 composed of epoxy resin or the like is charged into the through holes 9 by a printing method or the like so that the insides of the through holes 9 are filled.

Then, as illustrated in FIG. 2H, holes having a smaller diameter than the through holes 9 are formed in a manner penetrating the insulating resin 11 that fills the through holes 9. The holes described here may be formed by a method similar to that used for forming the through holes 9.

When the holes having a smaller diameter than the through holes 9 are formed in the insulating resin 11 in a penetrating manner, a structure is formed that the insulating resin 11 having a given thickness is provided on the inner wall surfaces of the through holes 9. This ensures insulation between the wiring section 5 formed in each through hole 9 at a process step described later and the intermediate layer 3 constructed from reinforced resin obtained by impregnating a carbon fiber material with a resin material.

After that, desmear treatment is applied for the purpose of roughening the insulating resin 11 provided on the inner wall surfaces of the through holes 9. Then, as illustrated in FIG. 2I, electroless plating and electroplating are performed onto the insulating resin 11 inside the through holes 9 and onto the prepreg 4, so that a copper (Cu) film is formed.

Then, as illustrated in FIG. 2J, on the copper (Cu) film formed on the prepreg 4, patterning is performed by using a dry film resist. Then, etching processing is performed, and then the dry film resist is peeled off. As a result, wiring sections 5 are formed. Here, in the examples illustrated in FIGS. 1 and 2I, single-layer wiring sections 5 are formed on the prepreg 4. However, a multilayered circuit may be formed by a buildup construction method or a batch stacking construction method.

Finally, a solder resist layer (insulating resin film) 12 is formed selectively onto the wiring sections 5 provided on the prepreg 4 and onto the prepreg 4. Then, surface treatment is applied onto the exposed surface part of the wiring sections 5 where the solder resist layer 12 is not provided. As a result, as illustrated in FIG. 2K, a device embedded substrate 10 illustrated in FIG. 1 is obtained.

As such, according to the manufacturing method for a device embedded substrate 10 of the first embodiment of the present invention, in a simple process, an intermediate layer 3 constructed from a reinforced resin material composed of a carbon fiber material having a thermal expansion coefficient of approximately 1 ppm/° C. to 10 ppm/° C. which is lower than that of a prepreg containing fibers composed of an insulating material such as glass cloth can be stacked and formed so as to surround the semiconductor device 2 in the part on the core board 1 except for the part where the through holes 9 are formed and the part where the semiconductor device 2 is provided.

Thus, a device embedded substrate 10 in which damage such as fracture and breakage in a built-in semiconductor device 2 is avoided and in which electrical connection between the semiconductor device 2 and a connection terminal section 6 of a core board 1 has improved reliability can be fabricated in a simple process.

Next, description is given concerning an example of application of the manufacturing method for a device embedded substrate 10 according to the first embodiment of the present invention implemented by the present inventor.

First, a core board and a semiconductor device were prepared. Specifically, prepared were a core board constructed from a 0.1 mm thick glass fiber reinforced plastics material and provided with connection terminal sections composed of copper (Cu) formed at a 120 μm pitch, and a semiconductor device constructed from silicon (Si) having a principal surface size of 5 mm×5 mm and a thickness of 0.1 mm in which gold (Au) stud bumps are formed on electrically conducting sections.

Then, the semiconductor device was flip-chip-mounted onto the connection terminal sections of the core board. The employed method of flip chip mounting was thermocompression bonding using non-conductive paste (NCP). The employed conditions in thermocompression bonding were a temperature of 200° C. and a working load of 45 g per bump. Here, since the non-conductive paste was used, the above-mentioned step of under-fill charging was omitted.

Then, reinforced resin that employs a carbon fiber material in a B-stage state and that has an opening slightly larger than the mounting region for a semiconductor device on the core board was stacked and cured on the core board under the given conditions such as a pressure of 3 MPa and a temperature of 180° C. The after-the-curing film thickness of this carbon fiber reinforced plastics was 0.1 mm.

Then, a prepreg constructed from a glass fiber reinforced plastics material was stacked and cured onto the above-mentioned reinforced resin and the semiconductor device and onto the lower face of the core board, with the thickness set to 0.1 mm.

After that, through holes that penetrate the prepreg, the intermediate layer, and the core board and that have a diameter of 0.3 mm were formed in the outside of the mounting region for a semiconductor device.

Then, insulating resin was changed into the through holes by a printing method or the like so that the insides of the through holes were filled. Then, holes having a diameter of 0.15 mm were formed in a penetrating manner in the insulating resin that fills the through holes.

After that, desmear treatment was applied. Then, electroless plating and electroplating were performed onto the insulating resin in the through holes and on the prepreg, so that a copper (Cu) film having a thickness of 25 μm was formed. Then, patterning was performed by using a dry film resist onto the copper (Cu) film formed on the prepreg. Then, etching processing was performed by using cupric chloride (CuCl₂) solution. Then, the dry film resist was peeled off so that wiring sections were formed.

Finally, a solder resist layer (insulating resin film) was formed selectively onto the wiring section provided on the prepreg and onto the prepreg. As a result, a device embedded substrate was obtained.

The present inventor performed a heat cycle test of 500 cycles with a temperature condition of −65° C. to 150° C. onto the embedded component substrate manufactured as described above. As a result, the ratio of resistance increase in the embedded component substrate was 8% at maximum relative to the initial value. On the other hand, in a comparison case of a device embedded substrate employing a glass fiber reinforced plastics material as the intermediate layer construction material, when a heat cycle test of 300 cycles was performed with the same temperature condition, the obtained ratio of resistance increase has exceeded 10%.

As seen from the description given above, according to the embedded component substrate of the first embodiment of the present invention, damage such as fracture and breakage is avoided in the semiconductor device built in the board. Further, the electrical connection between the semiconductor device and the connection terminal sections of the core board has improved reliability.

### Second Embodiment

Next, a second embodiment of the present invention is described below. First, the structure of a device embedded substrate according to a second embodiment of the present invention is described below. Then, description is given concerning a manufacturing method for a device embedded substrate according to the second embodiment of the present invention and an example of application of this method implemented by the present inventor.

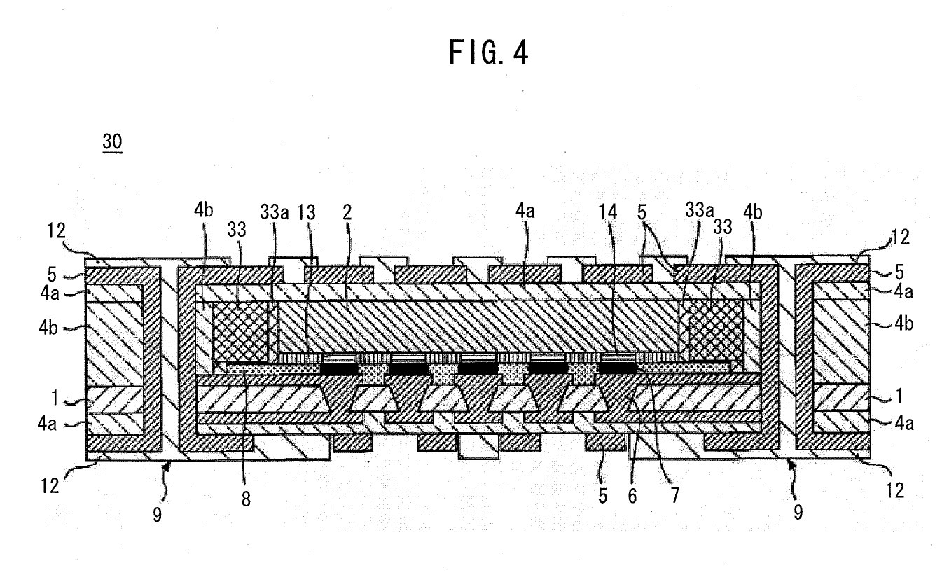

FIG. 4 is a sectional view of a device embedded substrate according to the second embodiment of the present invention. In FIG. 4, like parts to those illustrated in FIG. 1 are designated by like numerals, and their detailed description is omitted.

In the embedded component substrate 10 according to the first embodiment of the present invention described with reference to FIG. 1 and the like, the intermediate layer 3 is stacked and formed so as to surround the semiconductor device 2 in the entirety of the surface of the core board 1 except for the part where through holes 9 are formed and the part where the semiconductor device 2 is provided.

In contrast, in the embedded component substrate 30 according to the second embodiment of the present invention, as illustrated in FIG. 4, an intermediate layer 33 composed of the same material as the intermediate layer 3 illustrated in FIG. 1 is provided only around the side faces of the semiconductor device 2 located between two through holes 9. Further, a prepreg 4b serving as an intermediate layer insulating part is provided around each through hole 9. That is, through holes 9 are not formed in the intermediate layer 33 provided around the side faces of the semiconductor device 2.

The prepreg 4b ensures insulation between the through hole 9 where the wiring section 5 is formed on the wall surface and the intermediate layer 33. Thus, the insulating resin 11 illustrated in FIG. 1 is not formed on the inner wall surface of the through hole 9 in the second embodiment.

Further, in the intermediate layer 33, in the side faces of the semiconductor device 2 and the part on the core board 1 side, the resin material 33a for including the carbon fiber material constituting the intermediate layer 33 or the resin material for including the glass fibers in the prepreg 4 stacked later on top is squeezed out by pressurization in the manufacturing process for the embedded component substrate 30.

Also in the present example, the intermediate layer 33 containing reinforced resin such as carbon fiber material that has a thermal expansion coefficient of approximately 1 ppm/° C. to 10 ppm/° C. which is lower than that of a prepreg containing fibers composed of an insulating material such as glass cloth is stacked and formed so as to surround the semiconductor device 2.

Thus, in comparison with a conventional embedded component substrate formed when a prepreg constructed from a glass fiber reinforced plastics material having an opening in the mounting region for a semiconductor device is stacked on a core board on which a semiconductor device is mounted, the present invention suppresses the occurrence of the problems of damage to the semiconductor device and poor electrical connection between the semiconductor device and the core board that are caused by the difference between the thermal expansion coefficients of the components constituting the embedded component substrate.

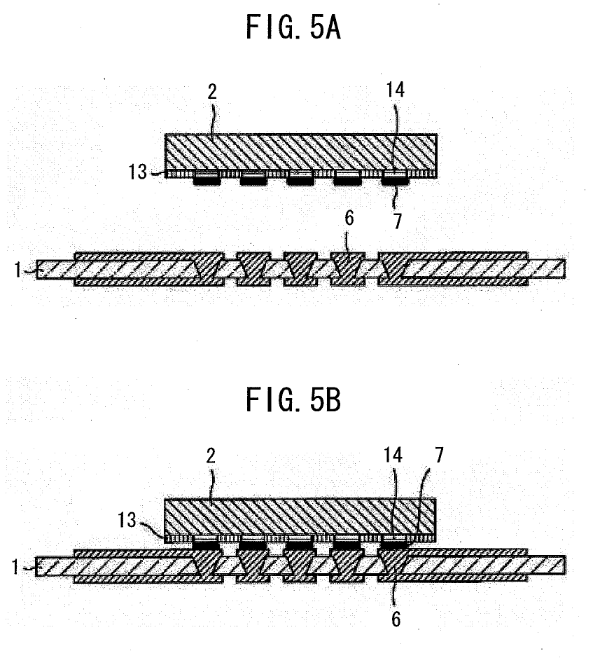

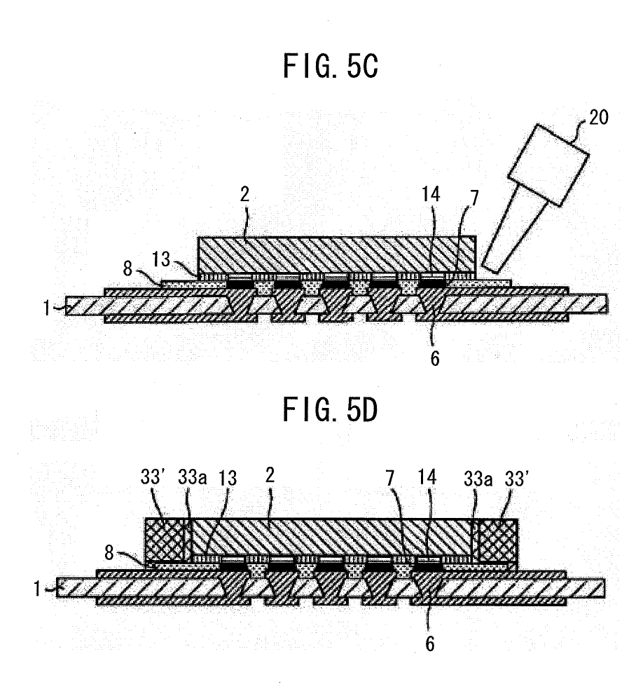

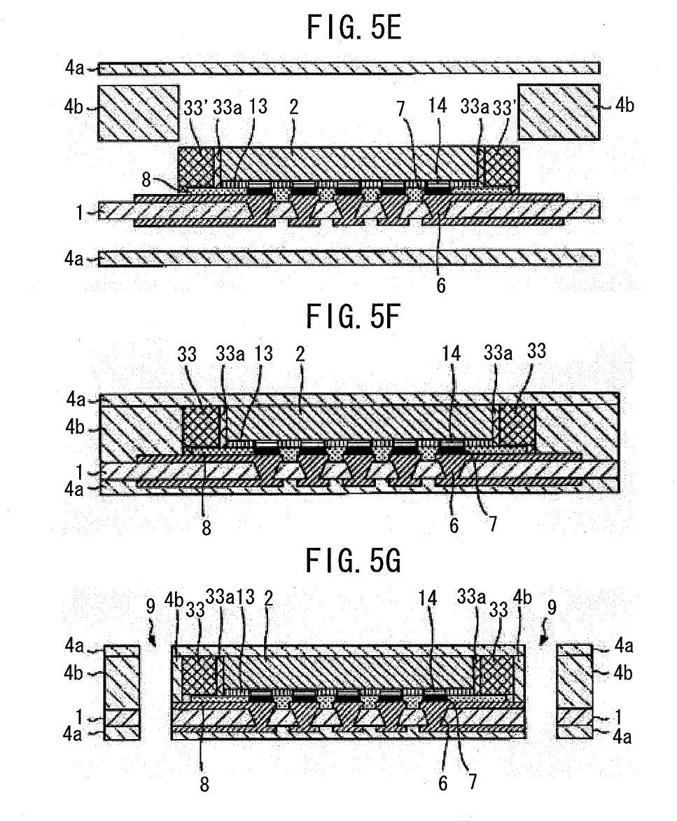

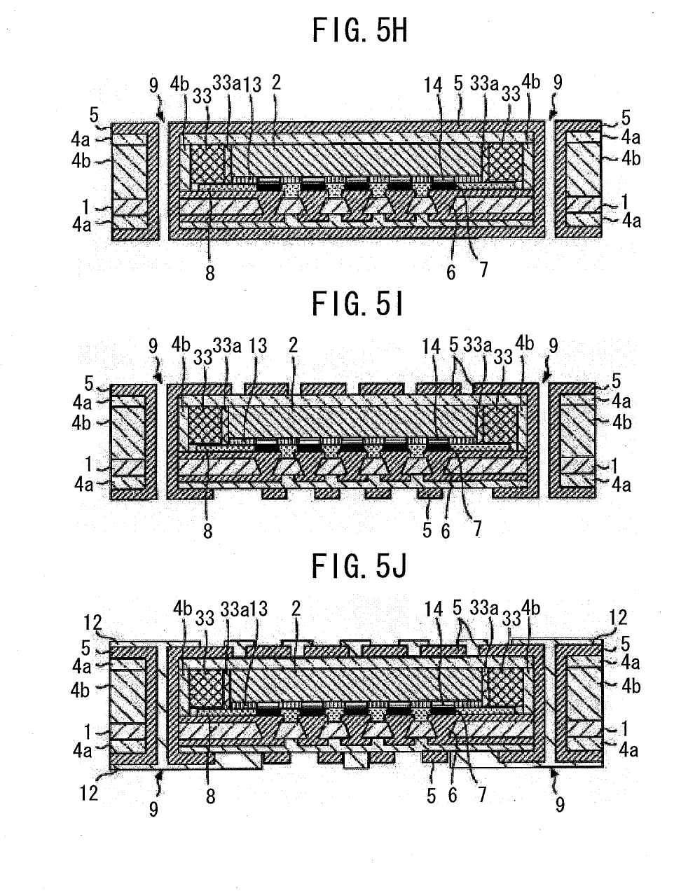

In the manufacturing method of the embedded component substrate 30, first, a core board 1 and a semiconductor device 2 are prepared as illustrated in FIG. 5A.

The core board 1 is constructed from a glass fiber reinforced plastics material or the like that employs glass fibers or the like as a reinforcing material and epoxy resin as a matrix resin. The thickness of the core board 1 may be set equal to, for example, approximately 0.03 mm to 0.3 mm.

In the core board 1, a plurality of connection terminal sections 6 that penetrate from the upper face to the lower face are formed at a given pitch. For example, the connection terminal sections 6 are constructed from copper (Cu) wiring or alternatively from copper (Cu) wiring on which a nickel (Ni) film and a gold (Au) film are formed.

On the other hand, the semiconductor device 2 is formed by a well-known wafer process, and includes silicon (Si), gallium arsenide (GaAs), or the like. The semiconductor device 2 may be composed of a so-called bare chip or a wafer level chip size package, and has a thickness of, for example, approximately 0.1 mm.

In the principal surface of the semiconductor device 2, an organic compound insulator film 13 such as a polyimide film is formed selectively. Then, in the part where the organic compound insulator film 13 is not formed, a plurality of electrically conducting sections 14 are formed. On each electrically conducting section 14, a protruding external connection terminal 7 referred to as a stud bump is formed. The external connection terminals 7 are composed of gold (Au) or the like.

The semiconductor device 2 is placed onto the core board 1 in a state that the connection terminal sections 6 of the core board 1 having the above-mentioned structure face the external connection terminals 7 provided in the semiconductor device 2.

Then, as illustrated in FIG. 5B, the semiconductor device 2 is mounted in a face-down state onto the connection terminal sections 6 of the core board 1. That is, flip chip mounting is performed. The employed method of flip chip mounting may be thermocompression bonding, ultrasonic jointing, or the like. Further, when solder is employed in the external connection terminals 7, the employed method of flip chip mounting may be a method of employing solder balls or a method of adhering solder onto the electrically conducting sections 14.

After that, as illustrated in FIG. 5C, paste-state under-fill material 8 is injected from a dispenser (not illustrated) through a nozzle 20, and then cured. The under-fill material 8 reinforces the connection between the core board 1 and the semiconductor device 2. Here, when the employed method of flip chip mounting is thermocompression bonding, the under-fill material 8 is injected into the gap between the core board 1 and the semiconductor device 2, then the semiconductor device 2 is flip-chip-mounted onto the core board 1, and then the under-fill material 8 is cured and shrunk.

Then, as illustrated in FIG. 5D, a cured-state reinforced resin 33′ that is constructed from a carbon fiber material and that has an opening slightly larger than the mounting region for the semiconductor device 2 on the core board 1 is stacked onto the core board 1, and then fixed by using adhesive (not illustrated) such as epoxy resin, so that an intermediate layer 33 illustrated in FIG. 4 is formed.

The reinforced resin material 33′ employing a carbon fiber material may be constructed from reinforced resin obtained by impregnating a carbon fiber material with a resin material having a thermal expansion coefficient of approximately 1 ppm/° C. to 10 ppm/° C. The employed carbon fiber material may be, for example, carbon fiber cloth, carbon fiber mesh, or carbon fiber nonwoven fabric that is fabricated with carbon fiber threads formed from bundles of carbon fibers. The resin material for including the carbon fiber material may be epoxy resin or the like.

Preferably, the film thickness of the intermediate layer 33 is equal to the thickness of the semiconductor device 2, and hence set equal to, for example, approximately 0.1 mm.

On the other hand, preferably, the width of the intermediate layer 33 is approximately 1/10 or greater of the width (the length in the longitudinal direction) of the semiconductor device 2. When the width of the intermediate layer 33 is smaller than approximately 1/10 of the width (the length in the longitudinal direction) of the semiconductor device 2, the effect of suppressing thermal expansion caused by temperature change can be degraded.

When the cured-state reinforced resin 33′ is stacked and fixed onto the core board 1, the resin material 33a for including the carbon fiber material constituting the intermediate layer 33 or the resin material for including the glass fibers in the prepreg 4 stacked later on top is squeezed out in the side faces of the semiconductor device 2 and the part on the core board 1 side.

Then, as illustrated in FIG. 5E, a prepreg 4b that is in a B-stage state and that has an opening larger than the mounting region for the semiconductor device 2 and the reinforced resin 33′ on the core board 1 is stacked and cured on the core board 1.

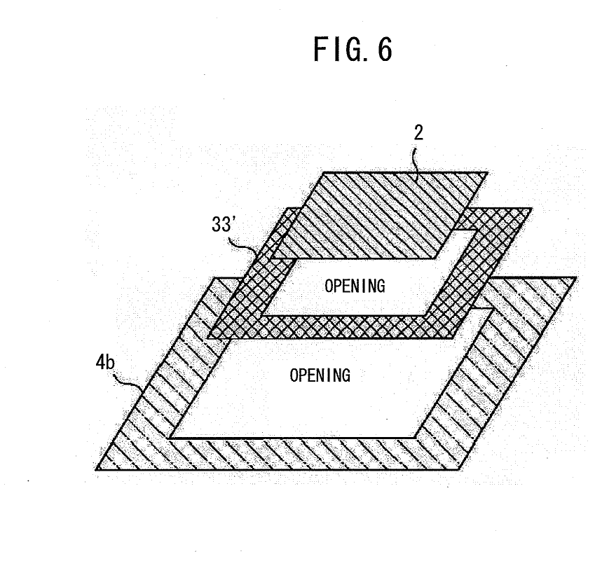

The positional relation between the reinforced resin 33′, the prepreg 4b, and the semiconductor device 2 at that time is illustrated in FIG. 6. FIG. 6 is a schematic diagram illustrating a perspective view of a situation that the reinforced resin 33′ having an opening slightly larger than the mounting region for the semiconductor device 2 on the core board 1 and the prepreg 4b that is in a B-stage state and that has an opening larger than the mounting region for the semiconductor device 2 and the reinforced resin 33′ on the core board 1 are provided on the core board 1. As illustrated in FIG. 6, an opening corresponding to the mounting region for the reinforced resin 33′ is formed approximately in the center of the prepreg 4b. Further, an opening slightly larger than the mounting region for the semiconductor device 2 is formed approximately in the center of the reinforced resin material 33′. Then, the semiconductor device 2 is located inside the opening.

Referring to FIG. 5E again, the prepreg 4a serving as an insulating layer is stacked onto the reinforced resin 33′ and the semiconductor device 2 and onto the lower face of the core board 1. The thickness of the prepreg 4a may be set equal to, for example, approximately 0.1 mm.

Here, similarly to the core board 1, the prepregs 4a and 4b is constructed from a glass fiber reinforced plastics material or the like that employs glass fibers or the like as a reinforcing material and epoxy resin or the like as a matrix resin.

Then, as illustrated in FIG. 5F, the prepreg 4 is heated and cured at a temperature of approximately 170° C. to 220° C.

After that, as illustrated in FIG. 5G, in the outside of the two side faces of the semiconductor device 2 mounted on the core board 1, that is, in the outside of the mounting region for the semiconductor device 2, through holes 9 that penetrate the prepregs 4a and 4b and the core board 1 are formed, for example, by drilling. Through holes 9 are not formed in the intermediate layer 33 provided only around the side faces of the semiconductor device 2. Thus, the prepreg 4b ensures insulation between the through hole 9 where the wiring section 5 is formed on the wall surface and the intermediate layer 33. This avoids the necessity of the insulation treatment on the inner wall surface of the through hole 9 (see FIG. 1), that is, the filling-up processing for the through hole 9 performed by using the insulating resin 11 (see FIG. 2G) and the through hole formation processing (see FIG. 2H) in the insulating resin 11. This simplifies the manufacturing process.

After that, as illustrated in FIG. 5H, electroless plating and electroplating are performed on the inner wall surface of the through hole 9 and on the prepreg 4, so that a copper (Cu) film is formed.

Then, as illustrated in FIG. 5I, on the copper (Cu) film formed on the prepreg 4, patterning is performed by using a dry film resist. Then, etching processing is performed, and then the dry film resist is peeled off. As a result, wiring sections 5 are formed. Here, in the example illustrated in FIG. 5H, single-layer wiring sections 5 are formed on the prepreg 4. However, a multilayered circuit may be formed by a buildup construction method or a batch stacking construction method.

Finally, a solder resist layer (insulating resin film) 12 is formed selectively onto the wiring sections 5 provided on the prepreg 4 and onto the prepreg 4. Then, surface treatment is applied onto the exposed surface part of the wiring sections 5 where the solder resist layer 12 is not provided. As a result, as illustrated in FIG. 5J, a device embedded substrate 30 illustrated in FIG. 4 is obtained.

As such, according to the manufacturing method for a device embedded substrate 30 of the second embodiment of the present invention, in a simple process, an intermediate layer 33 constructed from a reinforced resin material composed of a carbon fiber material having a thermal expansion coefficient of approximately 1 ppm/° C. to 10 ppm/° C. which is lower than that of a prepreg containing fibers composed of an insulating material such as glass cloth can be stacked and formed so as to surround the semiconductor device 2 in the part on the core board 1 except for the part where the through holes 9 are formed and the part where the semiconductor device 2 is provided.

Thus, a device embedded substrate 30 in which damage such as fracture and breakage in a built-in semiconductor device 2 is avoided and in which electrical connection between the semiconductor device 2 and a connection terminal section 6 of a core board 1 has improved reliability can be fabricated in a simple process.

Then, according to the manufacturing method for a device embedded substrate 30 of the second embodiment of the present invention, as illustrated in FIG. 5G, through holes 9 that penetrate the prepregs 4a and 4b and the core board 1 are formed in the outside of the mounting region for the semiconductor device 2, while through holes 9 are not formed in the intermediate layer 33 provided only around the side faces of the semiconductor device 2. Thus, the prepreg 4b ensures insulation between the through hole 9 where the wiring section 5 is formed on the wall surface and the intermediate layer 33. This avoids the necessity of the insulation treatment on the inner wall surface of the through hole 9 (see FIG. 1). This simplifies the manufacturing process.

Next, description is given below concerning an example of application (part 1) of the manufacturing method for a device embedded substrate 30 according to the second embodiment of the present invention implemented by the present inventor.

First, a core board and a semiconductor device were prepared. Specifically, prepared were a core board constructed from a 0.2 mm thick glass fiber reinforced plastics material and provided with connection terminal sections composed of copper (Cu) formed at a 250 μm pitch, and a semiconductor device that included gallium arsenide (GaAs) having a principal surface size of 2 mm×3 mm and a thickness of 0.2 mm in which gold (Au) plating bumps were formed on electrically conducting sections. Then, films of nickel (Ni) and gold (Au) were formed on the surface of the connection terminal sections of the core board.

Then, the semiconductor device was flip-chip-mounted onto the connection terminal sections of the core board. The employed method of flip chip mounting was ultrasonic jointing. As for the conditions of ultrasonic jointing, the temperature was 200° C., the working load was set to be 15 g per bump, and ultrasonic waves of 45 kHz were applied for 1 second. After that, under-fill material at 100° C. was charged between the semiconductor device and the core board, and then heated at a temperature of 150° C. for 1 hour so that the under-fill material was cured.

Then, on the core board, a cured-state reinforced resin material constructed from a carbon fiber material that has a principal surface size of 6 mm×7 mm and a thickness of 0.2 mm and that has an opening serving as the mounting region for the above-mentioned semiconductor device having a size of 2 mm×3 mm was bonded onto the core board by using adhesive.

Then, a B-stage state prepreg that is constructed from a glass fiber reinforced plastics material and that has an opening larger than the semiconductor device on the core board and the above-mentioned mounting region in the reinforced resin material was stacked on the core board. Then, the board was cured under a pressure of 3 MPa and a heating condition of 180° C. such that a thickness of 0.2 mm may be obtained after the curing.

Then, a prepreg constructed from a glass fiber reinforced plastics material and having a thickness of 0.1 mm was stacked and cured on the reinforced resin employing a carbon fiber material, on the semiconductor device 2, and on the lower face of the core board 1.

After that, through holes having a diameter of 0.2 mm were formed in the part outside the region where the semiconductor device and the cured reinforced resin employing a carbon fiber material were provided.

Then, desmear treatment was applied. Then, electroless plating and electroplating were performed on the inner wall surface of the through hole so that a copper (Cu) film having a thickness of 25 μm was formed. Then, patterning was performed by using a dry film resist onto the copper (Cu) film formed on the prepreg. Then, etching processing was performed by using cupric chloride (CuCl₂) solution. Then, the dry film resist was peeled off so that wiring sections were formed.

Finally, a solder resist layer (insulating resin film) was formed selectively onto the wiring section provided on the prepreg and onto the prepreg. As a result, a device embedded substrate was obtained.

The present inventor performed a heat cycle test of 500 cycles with a temperature condition of −65° C. to 150° C. onto the embedded component substrate manufactured as described above. As a result, the ratio of resistance increase in the embedded component substrate was 7% at maximum relative to the initial value. On the other hand, in a comparison case of a device embedded substrate employing a glass fiber reinforced plastics material as the intermediate layer construction material, when a heat cycle test of 300 cycles was performed with the same temperature condition, the obtained ratio of resistance increase has exceeded 10%.

As seen from the description given above, according to the embedded component substrate of the second embodiment of the present invention, damage such as fracture and breakage is avoided in the semiconductor device built in the board. Further, the electrical connection between the semiconductor device and the connection terminal sections of the core board has improved reliability.

The present inventor further implemented an example of application (part 2) of the manufacturing method for a device embedded substrate 30 according to the second embodiment of the present invention.

First, a core board and a semiconductor device were prepared. Specifically, prepared were a core board constructed from a 0.2 mm thick glass fiber reinforced plastics material and provided with connection terminal sections composed of copper (Cu) formed at a 200 μm pitch, and a semiconductor device that was constructed from silicon (Si) having a principal surface size of 6 mm×6 mm and a thickness of 0.1 mm in which soldering bumps were formed on electrically conducting sections. Then, films of nickel (Ni) and gold (Au) were formed on the surface of the connection terminal sections of the core board.

Then, the semiconductor device was flip-chip-mounted onto the connection terminal sections of the core board by using flux and a flip chip bonder. As for the condition of this mounting, the temperature was set to be 200° C. After that, under-fill material at 100° C. was charged between the semiconductor device and the core board, and then heated at a temperature of 150° C. for 1 hour so that the under-fill material was cured.

Then, on the core board, a cured-state reinforced resin material constructed from a carbon fiber material that has a principal surface size of 10 mm×10 mm and a thickness of 0.2 mm and that has an opening serving as the mounting region for the above-mentioned semiconductor device having a size of 6 mm×6 mm was bonded onto the core board by using adhesive. Then, a B-stage state prepreg that is constructed from a glass fiber reinforced plastics material and that has an opening larger than the semiconductor device on the core board and the above-mentioned mounting region in the reinforced resin material was stacked on the core board. Then, the board was cured under a pressure of 3 MPa and a heating condition of 180° C. such that a thickness of 0.1 mm was obtained after the curing.

Then, a prepreg constructed from a glass fiber reinforced plastics material and having a thickness of 0.1 mm was stacked and cured on the reinforced resin employing a carbon fiber material, on the semiconductor device 2, and on the lower face of the core board 1.

After that, through holes having a diameter of 0.2 mm were formed in the part outside the region where the semiconductor device and the cured reinforced resin employing a carbon fiber material were provided.

Then, desmear treatment was applied. Then, electroless plating and electroplating were performed on the inner wall surface of the through hole so that a copper (Cu) film having a thickness of 25 μm was formed. Then, patterning was performed by using a dry film resist onto the copper (Cu) film formed on the prepreg. Then, etching processing was performed by using cupric chloride (CuCl₂) solution. Then, the dry film resist was peeled off so that wiring sections were formed.

Finally, a solder resist layer (insulating resin film) was formed selectively onto the wiring section provided on the prepreg and onto the prepreg. As a result, a device embedded substrate was obtained.

The present inventor performed a heat cycle test of 500 cycles with a temperature condition of −65° C. to 150° C. onto the embedded component substrate manufactured as described above. As a result, the ratio of resistance increase in the embedded component substrate was 8% at maximum relative to the initial value. On the other hand, in a comparison case of a device embedded substrate employing a glass fiber reinforced plastics material as the intermediate layer construction material, when a heat cycle test of 300 cycles was performed with the same temperature condition, the obtained ratio of resistance increase has exceeded 10%.

As seen from the description given above, according to the embedded component substrate of the second embodiment of the present invention, damage such as fracture and breakage is avoided in the semiconductor device built in the board. Further, the electrical connection between the semiconductor device and the connection terminal sections of the core board has improved reliability.

### Third Embodiment

Next, a third embodiment of the present invention is described below.

In the above-mentioned second embodiment of the present invention, at the process step illustrated in FIG. 5D, the cured-state reinforced resin 33′ employing a carbon fiber material is stacked and fixed onto the core board 1 by using adhesive so that the intermediate layer 33 illustrated in FIG. 2 is formed. However, the present invention is not limited to this mode. That is, a reinforced resin material composed of a non-cured state carbon fiber material may be employed.

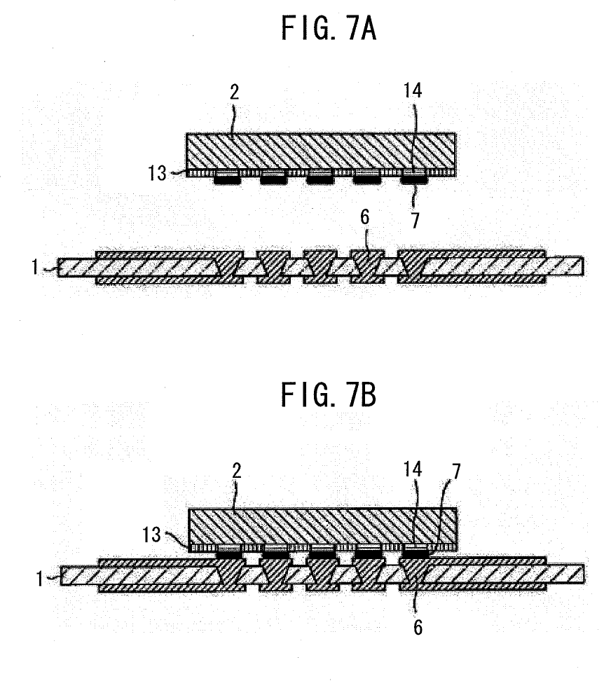

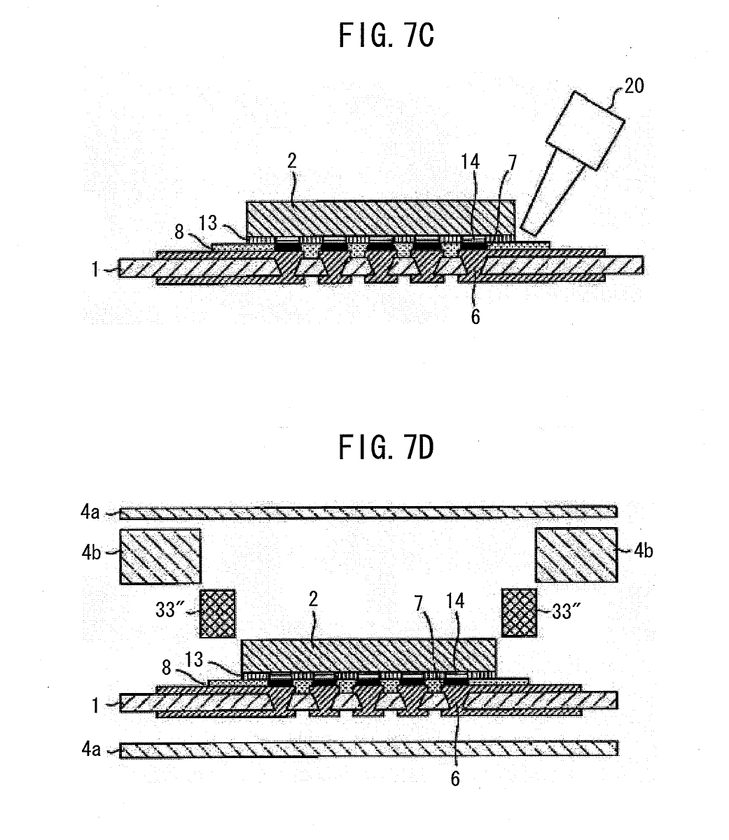

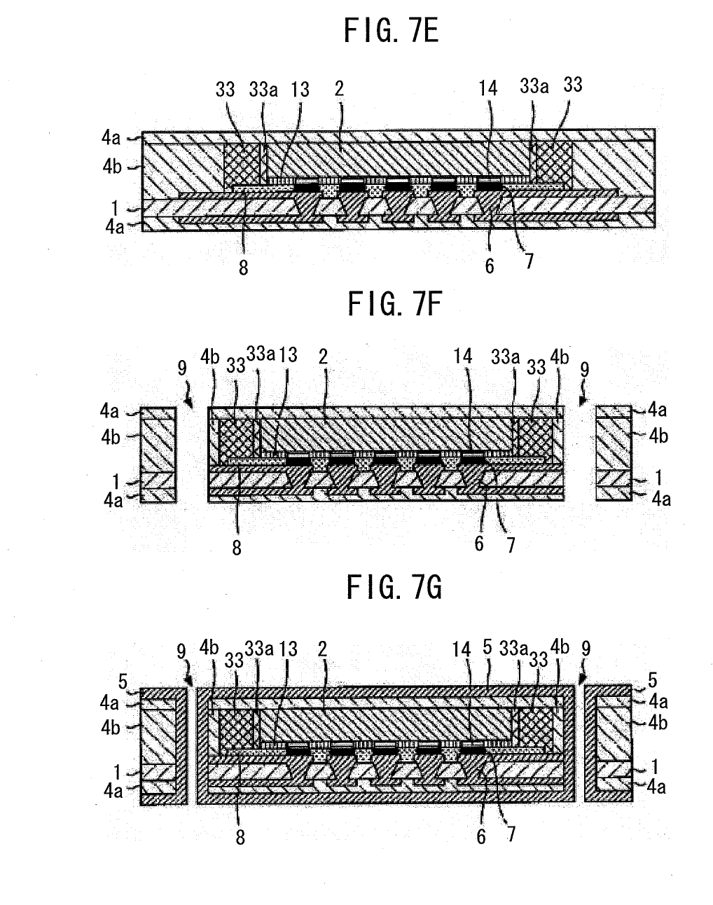

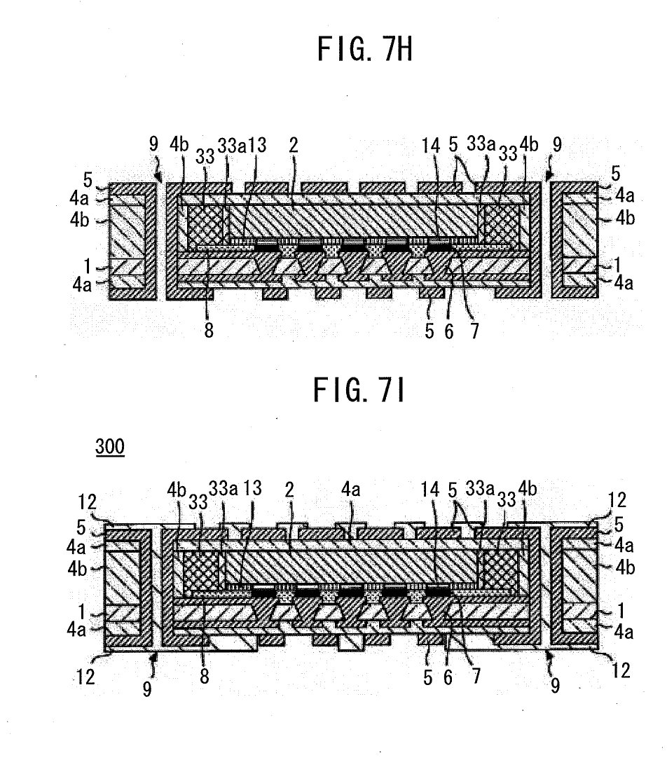

In the following description, a manufacturing method for the embedded component substrate according to the third embodiment of the present invention is described below with reference to FIGS. 7A to 7I. Then, description is given concerning an example of application of this method implemented by the present inventor. In FIGS. 7A to 7I, like parts to those illustrated in FIGS. 5A to 5J are designated by like numerals, and their detailed description is omitted.

First, as illustrated in FIG. 7A, a core board 1 and a semiconductor device 2 are prepared.

In the core board 1, a plurality of connection terminal sections 6 that penetrate from the upper face to the lower face are formed at a given pitch.

In the principal surface of the semiconductor device 2, an organic compound insulator film 13 such as a polyimide film is formed selectively. Then, in the part where the organic compound insulator film 13 is not formed, a plurality of electrically conducting sections 14 are formed. On each electrically conducting section 14, a protruding external connection terminal 7 referred to as a stud bump is formed.

The semiconductor device 2 is placed onto the core board 1 in a state that the connection terminal sections 6 of the core board 1 having the above-mentioned structure face the external connection terminals 7 provided in the semiconductor device 2.

Then, as illustrated in FIG. 7B, the semiconductor device 2 is mounted in a face-down state onto the connection terminal sections 6 of the core board 1. That is, flip chip mounting is performed.

After that, as illustrated in FIG. 7C, paste-state under-fill material 8 is injected from a dispenser (not illustrated) through a nozzle 20, and then cured. Thus, the under-fill material 8 reinforces the connection between the core board 1 and the semiconductor device 2.

Then, as illustrated in FIG. 7D, a reinforced resin material 33″ that is constructed from a carbon fiber material in a B-stage state and that has an opening slightly larger than the mounting region for the semiconductor device 2 on the core board 1 is stacked onto the core board 1.

The reinforced resin material 33″ employing a carbon fiber material may be constructed from reinforced resin obtained by impregnating a carbon fiber material with a resin material having a thermal expansion coefficient of approximately 1 ppm/° C. to 10 ppm/° C. The employed carbon fiber material may be, for example, carbon fiber cloth, carbon fiber mesh, or carbon fiber nonwoven fabric that is fabricated with carbon fiber threads formed from bundles of carbon fibers and that is oriented so as to extend in the directions of surface broadening. The resin material for including the carbon fiber material may be epoxy resin or the like.

It is preferable that the film thickness of the intermediate layer 33 obtained after the reinforced resin 33″ is cured in the subsequent process step is equal to the thickness of the semiconductor device 2. Thus, the thickness is set equal to, for example, approximately 0.1 mm.

On the other hand, preferably, the width of the intermediate layer 33 is approximately 1/10 or greater of the width (the length in the longitudinal direction) of the semiconductor device 2. This is because when the width of the intermediate layer 33 is smaller than approximately 1/10 of the width (the length in the longitudinal direction) of the semiconductor device 2, the effect of suppressing thermal expansion caused by temperature change is degraded.

Further, a B-stage state prepreg 4b constructed from a glass fiber reinforced plastics material or the like that employs glass fibers as a reinforcing material and epoxy resin or the like as a matrix resin and that has an opening larger than the mounting region for the semiconductor device 2 and the reinforced resin 33″ on the core board 1 is stacked and cured on the core board 1.

Then, a B-stage state prepreg 4a constructed from a glass fiber reinforced plastics material that employs glass fibers as a reinforcing material and epoxy resin or the like as a matrix resin is stacked onto the cured reinforced resin 33″ and the semiconductor device 2 and onto the lower face of the core board 1, and then cured such that the after-the-curing thickness of the prepreg 4a is equal to, for example, approximately 0.1 mm as illustrated in FIG. 7E. Then, in the side faces of the semiconductor device 2 and the part on the core board 1 side, the resin material 33a for including the carbon fiber material that constitutes the intermediate layer 33 or the resin material for including the glass fibers in the prepreg 4 thereon is squeezed out.

After that, as illustrated in FIG. 7F, in the outside of the two side faces of the semiconductor device 2 mounted on the core board 1, that is, in the outside of the mounting region for the semiconductor device 2, through holes 9 that penetrate the prepregs 4a and 4b and the core board 1 are formed, for example, by drilling. Through holes 9 are not formed in the intermediate layer 33 provided only around the side faces of the semiconductor device 2 in this example. Thus, the prepreg 4b ensures insulation between the through hole 9 where the wiring section 5 is formed on the wall surface and the intermediate layer 33. This avoids the necessity of the insulation treatment on the inner wall surface of the through hole 9 (see FIG. 1), that is, the filling-up processing for the through hole 9 performed by using the insulating resin 11 (see FIG. 2G) and the through hole formation processing (see FIG. 2H) in the insulating resin 11. This simplifies the manufacturing process.

After that, as illustrated in FIG. 7G, electroless plating and electroplating are performed on the inner wall surface of the through hole 9 and on the prepreg 4, so that a copper (Cu) film is formed.

Then, as illustrated in FIG. 7H, on the copper (Cu) film formed on the prepreg 4, patterning is performed by using a dry film resist. Then, etching processing is performed, and then the dry film resist is peeled off. As a result, wiring sections 5 are formed. Here, in the example illustrated in FIG. 7H, single-layer wiring sections 5 are formed on the prepreg 4. However, a multilayered circuit may be formed by a buildup construction method or a batch stacking construction method.

Finally, a solder resist layer (insulating resin film) 12 is formed selectively onto the wiring sections 5 provided on the prepreg 4 and onto the prepreg 4. Then, surface treatment is applied onto the exposed surface part of the wiring sections 5 where the solder resist layer 12 is not provided. As a result, as illustrated in FIG. 7I, a device embedded substrate 300 is obtained.

As such, according to the manufacturing method for a device embedded substrate 300 of the third embodiment of the present invention, in a simple process, an intermediate layer 33 constructed from a reinforced resin material composed of a carbon fiber material having a thermal expansion coefficient of approximately 1 ppm/° C. to 10 ppm/° C. which is lower than that of a prepreg containing fibers composed of an insulating material such as glass cloth can be stacked and formed so as to surround the semiconductor device 2 in the part on the core board 1 except for the part where the through holes 9 are formed and the part where the semiconductor device 2 is provided.

Thus, a device embedded substrate 300 in which damage such as fracture and breakage in a built-in semiconductor device 2 is avoided and in which electrical connection between the semiconductor device 2 and a connection terminal section 6 of a core board 1 has improved reliability can be manufactured in a simple process.

Then, according to the manufacturing method for a device embedded substrate 300 of the third embodiment of the present invention, as illustrated in FIG. 7F, through holes 9 that penetrate the prepregs 4a and 4b and the core board 1 are formed in the outside of the mounting region for the semiconductor device 2, while through holes 9 are not formed in the intermediate layer 33 provided only around the side faces of the semiconductor device 2. Thus, the prepreg 4b ensures insulation between the through hole 9 where the wiring section 5 is formed on the wall surface and the intermediate layer 33. This avoids the necessity of the insulation treatment on the inner wall surface of the through hole 9 (see FIG. 1). This simplifies the manufacturing process.

Next, description is given concerning an example of application of the manufacturing method for a device embedded substrate 300 according to the third embodiment of the present invention implemented by the present inventor.

First, a core board and a semiconductor device were prepared. Specifically, prepared were a core board constructed from a 0.1 mm thick glass fiber reinforced plastics material and provided with connection terminal sections composed of copper (Cu) formed at a 100 μm pitch, and a semiconductor device constructed from silicon (Si) having a principal surface size of 5 mm×5 mm and a thickness of 0.1 mm in which gold (Au) stud bumps are formed on electrically conducting sections.

Then, the semiconductor device was flip-chip-mounted onto the connection terminal sections of the core board. The employed method of flip chip mounting was thermocompression bonding using non-conductive paste (NCP). The employed conditions in thermocompression bonding were a temperature of 200° C. and a working load of 40 g per bump. Here, since the non-conductive paste was used, the above-mentioned step of under-fill charging was omitted.

Then, a B-stage state reinforced resin material constructed from a carbon fiber material that has a principal surface size of 8 mm×8 mm and a thickness of 0.1 mm and that has an opening corresponding to the mounting region for the above-mentioned semiconductor device having a size of 5 mm×5 mm and a prepreg that is constructed from a glass fiber reinforced plastics material in a B-stage state and that has an opening larger than the mounting region for the semiconductor device and above-mentioned reinforced resin are stacked on the core board, and then cured under a pressure of 3 MPa and a heating condition of 180° C. such that the after-the-curing thickness may be equal to 0.1 mm.

Then, a prepreg constructed from a glass fiber reinforced plastics material and having a thickness of 0.1 mm was stacked and cured on the reinforced resin employing a carbon fiber material, on the semiconductor device, and on the lower face of the core board.

After that, through holes having a diameter of 0.2 mm were formed in the part outside the region where the semiconductor device and the cured reinforced resin employing a carbon fiber material were provided.

Then, desmear treatment was applied. Then, electroless plating and electroplating were performed on the inner wall surface of the through hole so that a copper (Cu) film having a thickness of 25 μm was formed. Then, patterning was performed by using a dry film resist onto the copper (Cu) film formed on the prepreg. Then, etching processing was performed by using cupric chloride (CuCl₂) solution. Then, the dry film resist was peeled off so that wiring sections were formed.

Finally, a solder resist layer (insulating resin film) was formed selectively onto the wiring section provided on the prepreg and onto the prepreg. As a result, a device embedded substrate was obtained.

The present inventor performed a heat cycle test of 500 cycles with a temperature condition of −65° C. to 150° C. onto the embedded component substrate manufactured as described above. As a result, the ratio of resistance increase in the embedded component substrate was 7% at maximum relative to the initial value. On the other hand, in a comparison case of a device embedded substrate employing a glass fiber reinforced plastics material as the intermediate layer construction material, when a heat cycle test of 300 cycles was performed with the same temperature condition, the obtained ratio of resistance increase has exceeded 10%.

As seen from the description given above, according to the embedded component substrate of the third embodiment of the present invention, damage such as fracture and breakage is avoided in the semiconductor device built in the board. Further, the electrical connection between the semiconductor device and the connection terminal sections of the core board has improved reliability.

The embodiments of the present invention have been described above in detail. However, the present invention is not limited to these particular embodiments. That is, various modifications and changes can be made within the spirit of the present invention described in the claims.

What is claimed is:

1. A board comprising:
a core board;
an electronic component arranged on the core board; and
an intermediate layer that includes resin containing carbon fibers and that surrounds sides of the electronic component.

2. The board according to claim 1, further comprising:
a plurality of through holes that penetrate the core board formed around the electronic component.

3. The board according to claim 2, further comprising:
insulating resin formed on inner wall surfaces of the through holes; and
wiring sections formed on the insulating resin in insides of the through holes.

4. The board according to claim 1, wherein
the intermediate layer includes:
a first part that is constructed from the resin containing carbon fibers and that is provided around the electronic component; and
a second part that is constructed from an insulating material and that is provided outside of the first part.

5. The board according to claim 4, further comprising:
a plurality of through holes that penetrate the second part and the core board formed around the electronic component.

6. The board according to claim 4, wherein
the insulating material is resin containing glass fibers.

7. The board according to claim 6, wherein
a thermal expansion coefficient of the resin containing glass fibers is greater than a thermal expansion coefficient of the resin containing carbon fibers.

8. The board according to claim 6, wherein
the resin containing glass fibers is impregnated glass fiber material within a resin material.

9. The board according to claim 1, further comprising:
a resin layer formed between the electronic component and the intermediate layer.

10. The board according to claim 1, wherein
a thermal expansion coefficient of the resin containing carbon fibers is about 1 ppm/° C. to 10 ppm/° C.

11. The board according to claim 1, wherein
the resin containing carbon fibers is impregnated carbon fiber material within a resin material.

12. The board according to claim 1, wherein
the electronic component is a semiconductor device.

13. The board according to claim 1, wherein
a thermal expansion coefficient of the electronic component is about 1 ppm/° C. to 10 ppm/° C.

14. A manufacturing method for a board comprising:
mounting an electronic component on a core board;
forming an intermediate layer on the core board by arranging resin containing carbon fibers that has an opening for a mounting region for the electronic component so as to surround side faces of the electronic component;
stacking insulating layers on upper faces of the intermediate layer and the electronic component and on a rear face of said core board;
forming through holes in the intermediate layer and the core board;
applying insulation treatment to the through holes; and
forming wiring sections in insides of the through holes and on the insulating layers.

15. A manufacturing method for a board comprising:
mounting an electronic component on a core board;
forming an intermediate layer on the core board by arranging resin containing carbon fibers that has an opening for a mounting region for the electronic component so as to surround side faces of the electronic component and by forming an intermediate layer insulating part outside of a part where the resin containing carbon fibers is provided;
stacking an insulating layer on upper faces of the intermediate layer and the electronic component and on a rear face of the core board;
forming through holes in the intermediate layer insulating part, the core board, and the insulating layers; and
forming wiring sections in insides of the through holes and on the insulating layers.

16. The manufacturing method for a board according to claim 15, wherein
the intermediate layer insulating part is formed after the resin containing carbon fibers in a cured state is bonded.

17. The manufacturing method for a board according to claim 15, wherein
the intermediate layer is formed by
arranging the resin containing carbon fibers in a B-stage state and then stacking and curing the intermediate layer insulating part outside of the resin containing carbon fibers.

18. The manufacturing method for a board according to claim 15, wherein
the intermediate layer insulating part is composed of resin containing glass fibers.

19. The manufacturing method for a board according to claim 14, wherein
the resin containing carbon fibers is formed by impregnating a carbon fiber material with a resin material.

20. The manufacturing method for a board according to claim 14, wherein
the electronic component is a semiconductor device.
